(19) United States
(12) Patent Application Publication
(10) Pub. No.: US 2002/0079517 A1
(43) Pub. Date: Jun. 27, 2002

(54) Semiconductor device capable of preventing corrosion of metal wires from CMP (chemical mechanical polishing) process

(76) Inventor: Hyung-Jun Kim, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 10/015,757

(22) Filed: Dec. 17, 2001

(30) Foreign Application Priority Data
Dec. 22, 2000 (KR) 2000-80891

(51) Int. Cl. H01L 27/10

(52) U.S. Cl. 257/207; 438/926

(57) ABSTRACT

A semiconductor device comprising a plurality of metal wire patterns, each of which includes main fine line patterns, main pad patterns and dummy fine line patterns, wherein an area ratio of the dummy fine line patterns, which are connected to the main pad patterns, to the entire wire patterns is less than 1% and lower than a ratio of the main fine line patterns to the entire wire patterns.

### FIELD OF THE INVENTION

The present invention relates to a semiconductor device capable of preventing a corrosion of metal wires and, more particularly, to a semiconductor device capable of preventing a corrosion of metal wires from a chemical mechanical polishing (CMP) process.

### DESCRIPTION OF THE PRIOR ART

Generally, wires of a semiconductor device have been formed by using a reactive ion etching (RIE) process. However, as the width of the wires becomes narrower, it is difficult to apply the RIE process to form wires so a damascene technology is introduced. In the damascene technology, a chemical polishing (CMP) process is necessary for an isolation of the wires. Accordingly, the CMP process for the Al or Cu wires is required. Al and Cu have lower hardness than tungsten (W), and also have a very high chemical activity, making the Al and Cu wires very susceptible to corrosion. Since the corrosion of the metal wires is fatal to the reliability of the semiconductor device, such corrosion has to be prevented.

The CMP process is a key process in forming wires when applying the damascene technology. Since the Al or Cu wire is the electrically and chemically active metal, after the CMP process, a NH₄OH or HF solution, which is used at the conventional post cleaning process, cannot be used at a post cleaning process so that, if an appropriate chemical cleaner capable of being used at the post cleaning process is not developed, the post cleaning process is performed by using deionized (DI) water.

When the DI water is used as a post-process cleaner, a fine line, which is connected to a large pad, is more heavily corroded than an adjacent wide line. Since the corrosion is observed at a wafer cleaning process after the CMP process, another cleaning solution has to be used instead of the DI water. Recently, the wires are formed with copper and a low k insulating layer so that a research of the aluminum damascene process is weaker than the copper process. Accordingly, researches of CMP slurry and the post process cleaner are insufficiently developed.

The basic method for suppressing corrosion is to change a position, in which an oxidation reaction occurs. Namely, it is to use a material, which is electrically and chemically much more active than a material used as the wire, as a sacrificial anode. However, this requires a complicated process in which the sacrificial anode has to be formed at the same pattern with main wires. Also, it is not easy to select metals which are much more active material than aluminum or copper, which is usually used to form the wire.

### SUMMARY OF THE INVENTION

It is, therefore, an object of the present invention to provide a semiconductor device capable of preventing corrosion of metal wire patterns formed with aluminum or copper from the chemical-mechanical polishing (CMP) process.

In accordance with an aspect of the present invention, there is provided a semiconductor device comprising a plurality of metal wire patterns, each of which includes fine line patterns and pad patterns, wherein an area ratio of the fine line pattern to the entire wire patterns is above 1%.

In accordance with another aspect of the present invention, there is provided a semiconductor device comprising a plurality of metal wire patterns, each of which includes main fine line patterns, main pad patterns and dummy fine line patterns, wherein an area ratio of the dummy fine line patterns, which are connected to the pad patterns, to the entire wire patterns is below 1% and lower than that of the main fine line patterns.

### BRIEF DESCRIPTION OF THE DRAWINGS

The above and other objects and features of the instant invention will become apparent from the following description of preferred embodiments taken in conjunction with the accompanying drawings, in which:

FIG. 1 is a schematic diagram showing a formation of metal wire patterns in accordance with a first embodiment of the present invention;

FIG. 2 is a schematic diagram showing a formation of metal wire patterns inserting dummy lines in accordance with a second embodiment of the present invention;

FIG. 3 is a schematic diagram showing a formation of metal wire patterns inserting dummy lines and large dummy pads in accordance with a third embodiment of the present invention; and

FIG. 4 is a schematic diagram showing a formation of metal wire patterns inserting dummy lines and large dummy pad pool in accordance with a fourth embodiment of the present invention.

### DETAILED DESCRIPTION OF THE PREFERRED EMBODIMENTS

Hereinafter, a method for preventing a corrosion of metal wire patterns formed with an aluminum or copper wire from the chemical-mechanical polishing (CMP) process will be described in detail referring to the accompanying drawings.

In order to basically prevent the corrosion of the metal wires formed with an Al or Cu wire according to the present invention, a dummy pattern, where corrosion can occur instead of a main wire pattern, is additionally inserted to a basic wire pattern. When a fine line pattern of sub-micron size is connected to a large pad pattern, the fine line pattern is easily corroded. This corrosion is a dependence of patterns because the large pad pattern and the fine line pattern are formed with the same material. Particularly, when an area ratio of the fine line pattern to the overall wire patterns including the fine line pattern and the large pad pattern is low, the corrosion easily occurs so that, as a dummy fine line pattern, when an area ratio of the dummy fine line pattern to the entire wire patterns including a fine line pattern, a large pad pattern and the dummy fine line pattern, is larger than an area ratio of the narrow main line to the entire wires, is formed, the corrosion of the fine line pattern can be prevented.

Two method embodiments for preventing the wire corrosion will be described according to the present invention.

A first method is to differently form a pattern from the prior pattern. Namely, it is to change an area ratio of the fine line pattern to the entire wire patterns.

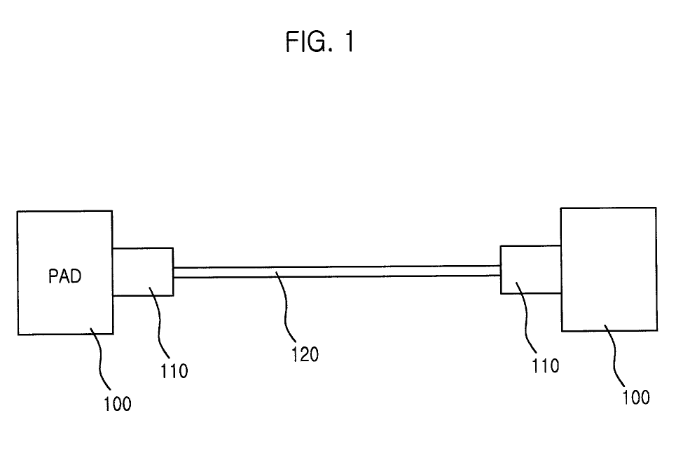

FIG. 1 is a schematic diagram showing the formation of metal wire patterns including a main fine line pattern 120, which has to be protected from corrosion, connected to large pad patterns 100 in accordance with a first embodiment of the present invention. After the CMP process of the wire patterns, the corrosion of the main fine line pattern 120 is caused when the main fine line pattern 120, when a width of the main fine line pattern is below 1 μm, is connected to the large pad patterns 100. When an area ratio of the main fine line pattern 120 to the entire wire patterns including the large pad patterns 100, connection pad pattern 110 and the main fine line pattern 120 is approximately above 1%, the corrosion can be prevented. A formula for preventing the corrosion is as follows:

(A/(Ap+Ac+A))×100)>1%

where, ‘A’ represents an area of the main fine line pattern 120, ‘Ap’ represents a gross area of the large pad patterns 100 and ‘Ac’ represents a gross area of the connection pad patterns 110.

A second method for preventing the corrosion of the main fine line pattern is to additionally insert a dummy fine line pattern to the basic wire patterns.

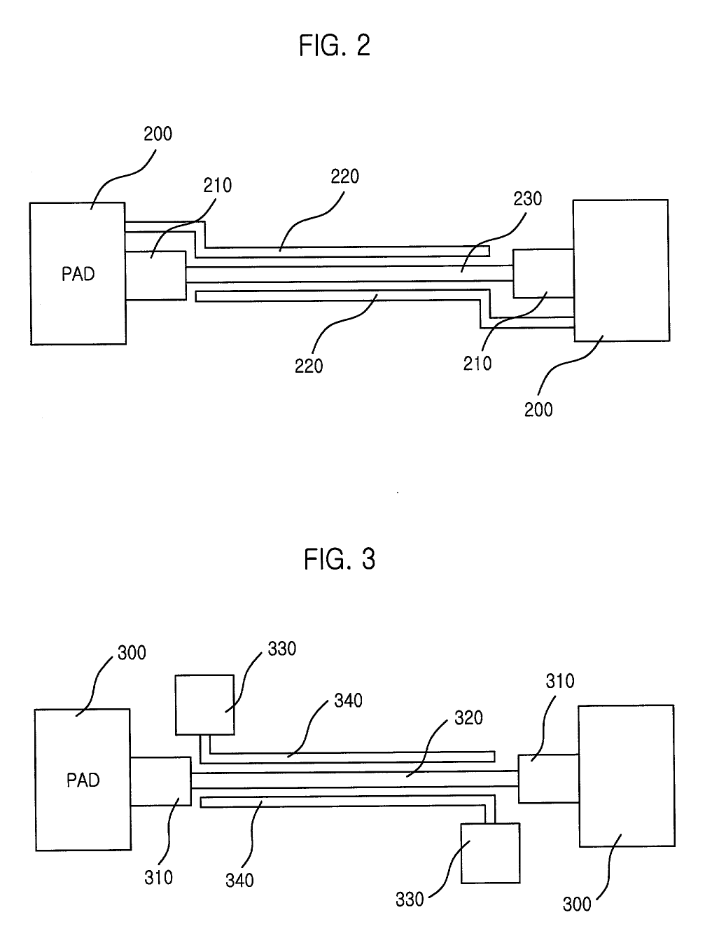

FIG. 2 is a schematic diagram showing a formation of metal wire patterns using dummy fine line patterns 220 connected to the large pad patterns 200 for preventing a corrosion of the main fine line pattern 230 in accordance with a second embodiment of the present invention.

Referring to FIG. 2, the dummy fine line patterns 220 are connected to the large pad patterns 200 and formed parallel with the main fine line pattern 230, which is desired to prevent the corrosion. When an area ratio of the dummy fine line patterns 220 to the entire wire patterns is much lower than an area ratio of the main fine line pattern 230 to the entire wire patterns and is below 1%, the corrosion of the main fine line pattern 230 can be prevented. A formula for preventing the corrosion according to this second embodiment is as follows:

(d/(Ap+Ac+A+d)×100)<1% and,

d/(Ap+Ac+A+d)<A/(Ap+Ac+A+d)

where, ‘d’ represents a gross area of the dummy fine line patterns 220, ‘Ap’ represents a gross area of the large pad patterns 200, ‘Ac’ represents a gross area of the connection pad patterns 210 and ‘A’ represents an area of the main fine line pattern 230. Also, the dummy fine line patterns 220 do not make any electric circuit.

FIG. 3 is a schematic diagram showing a formation of metal wire patterns using dummy fine line patterns 340 connected to large dummy pad patterns 330 for preventing the corrosion of a main fine line pattern 320 in accordance with a third embodiment of the present invention of the present invention. The large dummy pad patterns 330 and the dummy fine line patterns 340 do not make any electric circuit.

A formula for preventing the corrosion of the main fine line pattern 320 is as follows:

(d/(D+d))×100<1% and,

(d/(D+d))<A/(Ap+Ac+A)

where, ‘d’ represents a gross area of the dummy fine line patterns 340 and ‘D’ represents an gross area of the large dummy pad patterns 330. Also, ‘A’ represents an area of the main fine line pattern 320, ‘Ap’ represents a gross area of the large pad patterns 300 and ‘Ac’ represents a gross area of connection pad patterns 310. At this time, the large dummy pad patterns 330 and the dummy fine line patterns 340 are electrically disconnected from the main wire patterns.

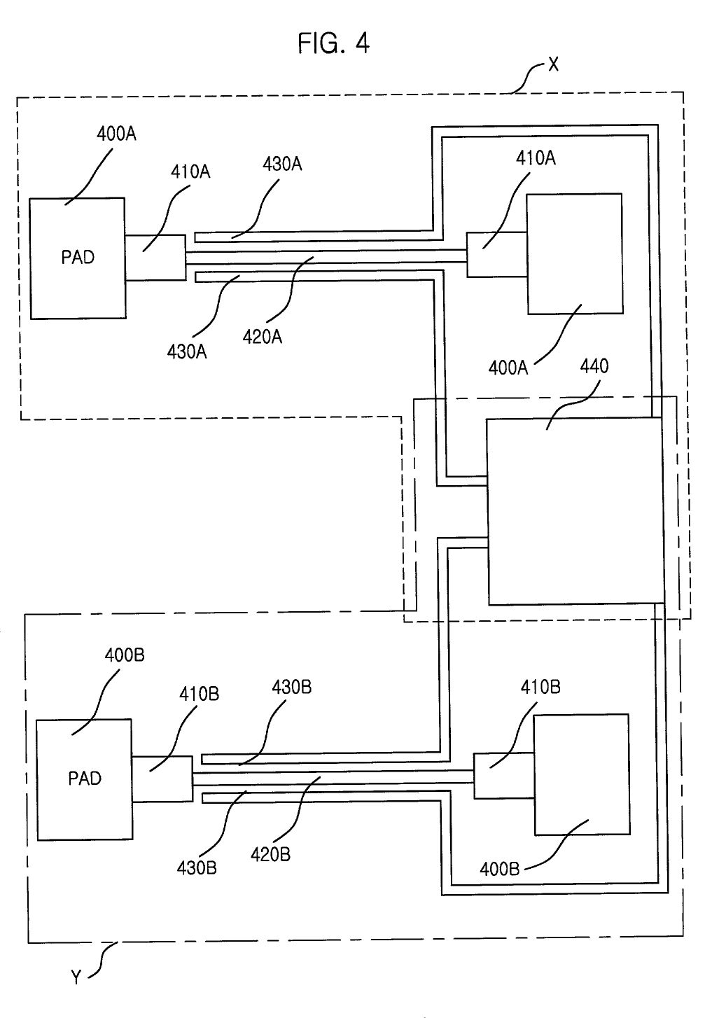

FIG. 4 is a schematic diagram showing a formation of metal wire patterns using a dummy pad pool 440 and dummy fine line patterns 430A and 430B to be used in several modules for the same purpose of preventing corrosion of the main fine line patterns 420A and 420B in accordance with a fourth embodiment of the present invention.

Referring to FIG. 4, in order to prevent the corrosion of the main fine line pattern 420A in an ‘X’ part, a formula for area ratios is as follows:

(d1/(D+d1+d2)×100)<1% and,

(d1/(D+d1+d2)<A1/(A1p+A1c+A1)

where, ‘d1’ represents a gross area of the dummy line patterns 430A, ‘d2’ represents a gross area of the dummy line patterns 430B, ‘D’ represents an area of the dummy pad pool 440. Also, ‘A1’ represents an area of the main fine line pattern 420A, ‘A1p’ represents a gross area of the large pad pattern 400A and ‘A1c’ represents a gross area of connection pad patterns 410A.

Also, in order to prevent the corrosion of the main fine line pattern 420B in a ‘Y’ part, a formula for area ratios in as follows:

(d2/(D+d1+d2)×100<1% and,

(d2/(D+d1+d2)<A2/(A2p+A2c+A2)

where, ‘d2’ represents a gross area of the dummy line patterns 430B, ‘d1’ represents a gross area of the dummy line patterns 430A, ‘D’ represents an area of the dummy pad pool 440. Also, ‘A2’ represents an area of the main fine line pattern 420B, ‘A2p’ represents a gross area of the large pad pattern 400B and ‘A2c’ represents a gross area of connection pad patterns 410B. The dummy pad pool 440 and the dummy fine line patterns 430A and 430B do not make any electric circuit.

Accordingly, the present invention can be applied in the damascene technology even if slurries for polishing metal wire patterns, such as Al or Cu wires, and cleaners, which are appropriate at a post cleaning process, are not developed.

While the present invention has been described with respect to the particular embodiments, it will be apparent to those skilled in the art that various changes and modifications may be made without departing from the spirit and scope of the invention as defined in the following claims.

What is claimed is:

1. A semiconductor device comprising:
a plurality of metal wire patterns, each of which includes a fine line pattern and pad patterns, wherein an area ratio of the fine line pattern to an overall wire pattern is greater than 1%.

2. The semiconductor device as recited in claim 1, wherein a width of the fine line pattern is below sub-micron.

3. The semiconductor device as recited in claim 1, wherein the pad patterns include connection pad patterns which electrically connect the pad patterns to the fine line pattern, said connection pad patterns being included in said overall wire pattern.

4. The semiconductor device as recited in claim 1, wherein the metal wire patterns are made of aluminum or copper.

5. A semiconductor device comprising:
a plurality of metal wire patterns, each of which includes main fine line patterns, main pad patterns and dummy fine line patterns, wherein an area ratio of the dummy fine line patterns, which are connected to the pad patterns, to an entire wire pattern is less than 1% and lower than that of an area ratio of the main fine line patterns to the entire wire pattern.

6. The semiconductor device as recited in claim 5, wherein the dummy fine line patterns are formed parallel with the main fine line patterns at a distance of a width of the main fine line pattern.

7. The semiconductor device as recited in claim 5, wherein the metal wire patterns are made of aluminum or copper wire.

8. The semiconductor device as recited in claim 5, wherein the dummy fine line patterns do not make any electric circuit.

9. The semiconductor device as recited in claim 5, wherein the metal wire patterns further include dummy pad patterns, to which the dummy fine line patterns are connected, wherein the dummy pad patterns and the dummy fine line patterns are electrically disconnected from the main fine line patterns and the main pad patterns.

10. The semiconductor device as recited in claim 5, wherein the metal wire patterns further include dummy pad pool patterns, to which the dummy fine line patterns are connected, wherein the dummy pad pool patterns and the dummy fine line patterns are electrically disconnected from the main fine line patterns and the main pad patterns.

11. The semiconductor device as recited in claim 5, wherein the metal wire patterns are made of aluminum or copper wire.
